(19) United States
(12) Patent Application Publication
(10) Pub. No.: US 2014/0306708 A1
(43) Pub. Date: Oct. 16, 2014

(54) Magnetic Resonance Apparatus with Group-by-Group Actuation of Transmission Antennas

(71) Applicants: Hans-Peter Fautz, Forchheim (DE); Matthias Gebhardt, Erlangen (DE); Franz Schmitt, Erlangen (DE)

(72) Inventors: Hans-Peter Fautz, Forchheim (DE); Matthias Gebhardt, Erlangen (DE); Franz Schmitt, Erlangen (DE)

(21) Appl. No.: 14/250,140

(22) Filed: Apr. 10, 2014

(30) Foreign Application Priority Data
Apr. 10, 2013 (DE) 102013206325.3

(51) Int. Cl. G01R 33/36

(52) U.S. Cl. CPC G01R 33/36; G01R 33/34092
USPC 324/314

(57) ABSTRACT

A magnetic resonance apparatus including transmission antennas that may be actuated in parallel by a control device of the magnetic resonance apparatus may be operated in a group mode. In the group mode, the transmission antennas are grouped into groups of transmission antennas. The actuation signals of transmission antennas within the respective group are in a respectively predefined relationship relative to one another. A respective group actuation signal for each of the groups of transmission antennas is prescribed for the control device by an operator. The control device carries out checks as to whether a group exposure value established based on the group actuation signals lies below a maximum admissible group exposure limit. If this is the case, the control device establishes the actuation signals for the individual transmission antennas based on the group actuation signals. If this is not the case, the control device carries out another measure.

This application claims the benefit of DE 10 2013 206 325.3, filed on Apr. 10, 2013, which is hereby incorporated by reference in its entirety.

### BACKGROUND

The present embodiments relate to a method of operation for a magnetic resonance apparatus.

Magnetic resonance apparatuses are known in various configurations. In the simplest case, the magnetic resonance apparatus has a single transmission antenna, by which a radiofrequency excitation signal is applied to an examination volume. Using the radiofrequency excitation signal, an examination object situated in the examination volume may be excited to emit magnetic resonance signals. In recent times, magnetic resonance apparatuses with a plurality of transmission antennas have also been developed. A respective actuation signal by the control device may be applied to the individual transmission antennas. Each actuation signal respectively uses one transmission channel. However, the number of transmission channels in the individual case during the operation of the magnetic resonance apparatus depends on the desired application and on the configuration and arrangement of the transmission antennas.

The greater the number of transmission channels is, the more complex and the more time-consuming the adjustment of the actuation signals (e.g., the B1 mapping) becomes. Establishing the actuation signals (e.g., the pulse design) is also time-consuming. Numerical instabilities may occur under certain circumstances when establishing the actuation signals.

The degrees of freedom of a system with n transmission antennas may be restricted to m degrees of freedom (e.g., with m<n). From a technical point of view, this may be realized as a hardware solution by virtue of the transmission channels being combined to a small a number of virtual transmission channels. Alternatively, the combination may be realized by software by virtue of only predetermined relationships of the amplitudes and/or phases relative to one another being admissible for the formed groups of transmission antennas. A software solution, for example, offers maximum flexibility and scaling while having relatively low costs.

In general, such a restriction of the degrees of freedom will be detrimental to the possible capabilities (e.g., detrimental to the achievable excitation homogeneity or a possible acceleration for spatially selective pulses). Nevertheless, the restriction of degrees of freedom may be expedient (e.g., because this results in a simpler pulse design).

When designing the pulse, the technical performance limits of the magnetic resonance apparatus are to be observed. However, independent of the technical performance limits, certain radiofrequency field strengths may not be exceeded so as not to endanger the examination object (e.g., a human). It is for this reason that there are guidelines (e.g., technical and/or legal) that, in general, prescribe the maximum allowable strength of radiofrequency excitation fields. It is known from practice for magnetic resonance antennas with individual antennas that the limits specified in the guidelines for the general case may be exceeded in the case of certain signals by a factor of, for example, approximately 2 to approximately 3 without endangering the examination object. However, such circumstances known for magnetic resonance antennas with individual antennas may not be simply transferred to magnetic resonance apparatuses in which a plurality of transmission antennas are present.

DE 10 2011 005 433 A1 has disclosed that a whole body antenna, embodied as a birdcage resonator, may be actuated in a conventional circular polarized (CP) mode (e.g., may be operated as an individual antenna). DE 10 2011 005 433 A1 has also disclosed that the individual transmission antennas of a transmission array may be actuated on their own and individually. Further, DE 10 2011 005 433 A1 discloses that the transmission mode is checked in each case and, depending on the transmission mode, control rules for establishing admissible actuation signals for the transmission antennas are set.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, in the case of a magnetic resonance apparatus with a plurality of transmission antennas, options, by which a technical capability of the transmission antennas may be employed as far as possible with no risk of exposing the examination object to an inadmissibility high radiofrequency excitation field, are provided.

According to one or more of the present embodiments, a method of operation is embodied such that the magnetic resonance apparatus may be operated in a group mode. In the group mode, the transmission antennas are grouped into groups of transmission antennas. In the group mode, the actuation signals of transmission antennas within the respective group are in a respectively predefined relationship relative to one another. In the group mode, a respective group actuation signal for each of the groups of transmission antennas is prescribed for the control device by an operator. In the group mode, the control device carries out a check as to whether a group exposure value established based on the group actuation signals lies below a maximum admissible group exposure limit. If this is the case, the actuation signals are established for the individual transmission antennas based on the group actuation signals, and the transmission antennas are actuated accordingly. If this is not the case, another measure is carried out.

Thus, a plurality of groups of transmission antennas are formed. At least one group of the plurality of groups includes a plurality of transmission antennas. Even a plurality of groups or all groups, respectively, include a plurality of transmission elements.

The method of operation according to one or more of the present embodiments is based on the concept of it being possible with an acceptable amount of outlay (e.g., using appropriate models or trials on non-living objects) to determine the maximum admissible group exposure limit when reducing the degrees of freedom in advance such that the examination object is not endangered even though the aforementioned guidelines are not observed. In this case, all group actuation signals and the actuation signals derived therefrom may be applied in the group mode if the group exposure value resulting by the group actuation signals remains below the group exposure limit.

The other measures may be determined according to requirements. By way of example, the control device, within the scope of the other measure, may scale the group control signals such that a scaled group exposure value established based on the scaled group actuation signals lies below the maximum admissible group exposure limit, establishes the actuation signals for the individual transmission antennas based on the scaled group actuation signals, and actuates the transmission antennas accordingly. The scaling is a reduction in relation to the amplitude of the group actuation signals. The scaling may also be combined with (e.g., inverted thereto) temporal stretching.

As an alternative to scaling, or in addition thereto, the control device may output a message to the operator within the scope of the other measure.

In one embodiment, the magnetic resonance apparatus is operable exclusively in the group mode. However, the magnetic resonance apparatus may be operable in an individual mode in addition to the group mode. In the individual mode, the transmission antennas may be actuated individually. In this case, a respective actuation signal for each of the transmission antennas is prescribed for the control device by the operator. In the individual mode, the control device carries out a check as to whether an individual exposure value established based on the actuation signals lies below a maximum admissible individual exposure limit, and if this is the case, actuates the transmission antennas according to the actuation signals. If this is not the case, the control device carries out a further measure. The individual exposure limit may have different value to that of the group exposure limit. If operation is also possible in the individual mode, the control device receives a mode signal from the operator and makes a decision based on the mode signal as to whether the magnetic resonance apparatus is operated in the group mode or in the individual mode. Therefore, the magnetic resonance apparatus may be operated in both modes in this case. At a given time, only one of the two modes is active.

Analogously to the group mode, the control device may scale the actuation signals within the scope of the further measure in the individual mode such that a scaled individual exposure value established based on the scaled actuation signals lies below the maximum admissible individual exposure limit and may actuate the transmission antennas according to the scaled actuation signals. In one embodiment, the control apparatus may output a message to the operator within the scope of the further measure.

### BRIEF DESCRIPTION OF THE DRAWINGS

FIGS. 1 and 2 show an example magnetic resonance apparatus in embodiments of operating modes; and

FIG. 3 shows a flowchart of one embodiment of a method.

### DETAILED DESCRIPTION

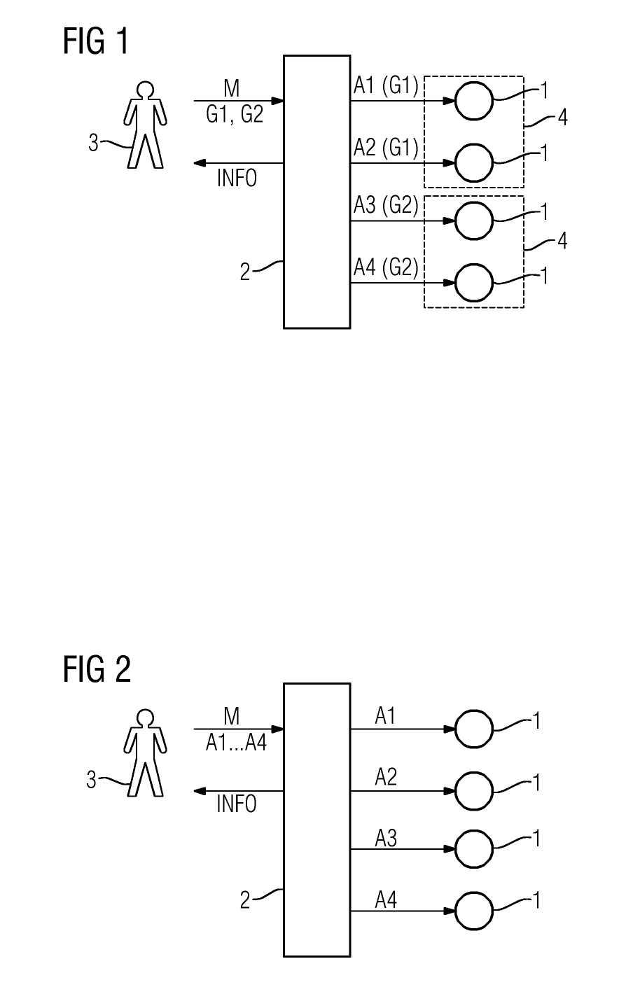

In accordance with FIGS. 1 and 2, one embodiment of a magnetic resonance apparatus has a plurality of transmission antennas 1. The depicted number of four transmission antennas 1 in FIGS. 1 and 2 is merely exemplary. The transmission elements 1 may be actuated in parallel by a control device 2 of the magnetic resonance apparatus. Thus, at a given time, a corresponding actuation signal A1 to A4 may be applied simultaneously to a plurality of the transmission antennas 1. The actuation signals A1 to A4 may be set independently from one another.

The magnetic resonance apparatus is operable at least in a group mode. The group mode is depicted in FIG. 1. The magnetic resonance apparatus may also be operable in an individual mode. The individual mode is depicted in FIG. 2. The two modes are alternatives to one another (e.g., at a given time, only one of the two modes is active).

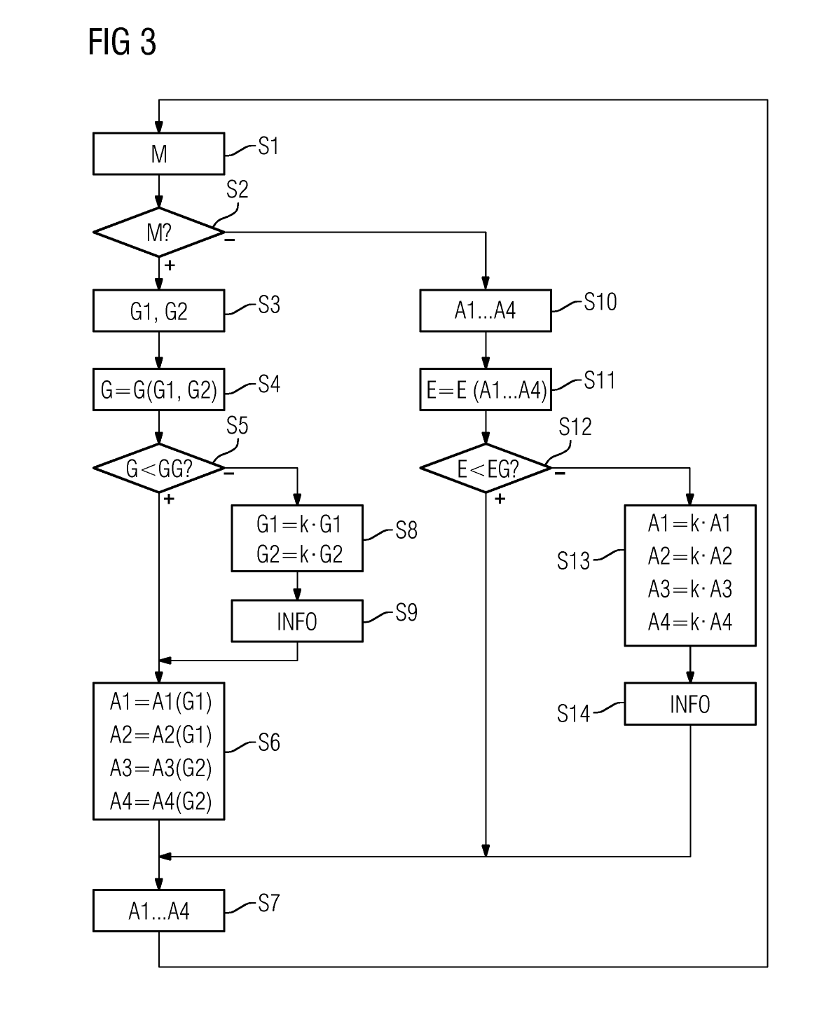

Hereinbelow, the method of operation according to one or more of the present embodiments is explained in more detail in conjunction with FIG. 3 and with additional reference to FIGS. 1 and 2.

According to FIG. 3, the control device 2 receives a mode signal M from an operator 3 in act S1. Based on the mode signal M, the control device 2 makes a decision in act S2 as to whether the magnetic resonance apparatus is operated in the group mode or in the individual mode.

If the magnetic resonance apparatus is operated in the group mode, the transmission antennas 1 as per FIG. 1 are grouped to form groups 4. The number of groups 4 may be determined according to circumstances. The number of groups 4 is less than the number of transmission antennas 1. In one embodiment, in accordance with the illustration of FIG. 1, two groups are formed. However, the illustration in FIG. 1, in which exactly two groups 4 are formed, is arbitrary. Each transmission antenna 1 is assigned to exactly one group 4. Due to the fact that the number of groups 4 is less than the number of transmission antennas 1, at least one of the groups 4 therefore includes more than one transmission antenna 1. In one embodiment, each group of a plurality of groups 4 or all of the groups 4 comprises a plurality of transmission antennas 1. The grouping depicted in FIG. 1, in which each group 4 includes exactly 2 transmission antennas 1, is arbitrary. Within the groups 4, the actuation signals A1 to A4 (e.g., the actuation signals A1 and A2) are, relative to one another, in a respective predefined relationship with respect to one another. For example, predetermined amplitude ratios and/or predetermined phase relationships may be defined.

In the group mode, a respective group actuation signal G1, G2 for each of the groups 4 is prescribed for the control device 2 by the operator 3 in act S3. In act S4, the control device 2 establishes a group exposure value G based on the group actuation signals G1, G2. In act S5, the control device 2 carries out a check as to whether the group exposure value G lies below a maximum admissible group exposure limit GG. If the group exposure value G lies below the maximum admissible group exposure limit GG, the control device 2, in act S6, establishes the actuation signals A1 to A4 for the individual transmission antennas 1 based on the group actuation signals G1, G2. In act S7, the control device 2 transmits the actuation signals A1 to A4 to the transmission antennas 1.

If, in act S5, the control device 2 has determined that the group exposure value G does not lie below the maximum admissible group exposure limit GG, the control device 2 carries out another measure in act S8 and/or act S9 (and optionally in further acts). For example, the control device 2 may scale the group actuation signals G1, G2 using a scaling factor k (0<k<1) (e.g., within the scope of act S8). In this case, the scaling factor k is determined such that a scaled group exposure value G established based on the scaled group actuation signals G1, G2 lies below the maximum admissible group exposure limit GG. As an alternative or in addition thereto, the control device 2 may output a message to the operator 3 in act S9.

If the act S8 is present, the control device 2 proceeds to act S6 after carrying out act S8 and the further steps of the no branch of act S5. Otherwise, acts S6 and S7 are bypassed.

By contrast, if the magnetic resonance apparatus is operated in the individual mode, the transmission antennas 1 are not grouped into groups 4. In the individual mode, the transmission antennas 1 instead maybe actuated individually by the control device 2.

In the individual mode, a respective actuation signal A1 to A4 for each of the transmission antennas 1 is prescribed for the control device 2 by the operator 3 in act S10. In act S11, the control device 2 establishes an individual exposure value E based on the actuation signals A1 to A4. In act S12, the control device 2 carries out a check as to whether the individual exposure value E lies below a maximum admissible individual exposure limit EG. If the individual exposure value E lies below the maximum admissible individual exposure limit EG, the control device 2 proceeds directly to act S7.

If, in act S12, the control device 2 has determined that the individual exposure value E does not lie below the maximum admissible individual exposure limit EG, the control device 2 carries out a further measure in act S13 and/or act S14 (and optionally in further acts). For example, the control device 2 may scale the actuation signals A1 to A4 using a scaling factor k (0<k<1), for example, within the scope of act S13. In this case, the scaling factor k is determined such that a scaled individual exposure value E established based on the scaled actuation signals A1 to A4 lies below the maximum admissible individual exposure limit EG. As an alternative or in addition thereto, the control device 2 may output a message to the operator 3 in act S14.

If the act S13 is present, the control device 2 proceeds to act S7 after carrying out act S13 and the further acts of the no branch of act S12. Otherwise, act S7 is bypassed.

Depending on mode signal M, the magnetic resonance apparatus is alternatively operated in the group mode or in the individual mode. Alternatively, the magnetic resonance apparatus may only be operated in the group mode. In this case, acts S1 and S2 and also S10 to S14 may be dispensed with in the flowchart of FIG. 3.

Although the invention was described and depicted in more detail by the exemplary embodiment, the invention is not restricted by the disclosed examples, and other variations may be derived from this by a person skilled in the art without departing from the scope of protection of the invention.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims can, alternatively, be made to depend in the alternative from any preceding or following claim, whether independent or dependent, and that such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method of operation for a magnetic resonance apparatus comprising a plurality of transmission antennas that are actuatable in parallel by a control device of the magnetic resonance apparatus, the method comprising:
operating the magnetic resonance apparatus in a group mode, wherein in the group mode, the plurality of transmission antennas are grouped into groups of transmission antennas, actuation signals of transmission antennas within the respective group are in a respectively predefined relationship relative to one another, and a respective group actuation signal is prescribed for each of the groups of transmission antennas for the control device by an operator,
wherein the operating of the magnetic resonance apparatus in the group mode comprises:
carrying out, with the control device, a check as to whether a group exposure value established based on the group actuation signals lies below a maximum admissible group exposure limit;
establishing the actuation signals for the individual transmission antennas based on the group actuation signals and actuating the transmission antennas accordingly when the group exposure value established based on the group actuation signals lies below the maximum admissible group exposure limit; and
carrying out another measure when the group exposure value established based on the group actuation signals does not lie below the maximum admissible group exposure limit.

2. The method of operation of claim 1, wherein carrying out the other measure comprises scaling, by the control device, the group actuation signals such that a scaled group exposure value established based on the scaled group actuation signals lies below the maximum admissible group exposure limit, establishing the actuation signals for the individual transmission antennas based on the scaled group actuation signals, and actuating the transmission antennas.

3. The method of operation of claim 1, wherein carrying out the other measure comprises outputting, by the control device, a message to the operator.

4. The method of operation of claim 2, wherein carrying out the other measure comprises outputting, by the control device, a message to the operator.

5. The method of operation of claim 1, wherein the magnetic resonance apparatus is operable in an individual mode, in which the plurality of transmission antennas are actuatable individually,
wherein in the individual mode, the method further comprises:
receiving, from the operator and for the control device, a respective actuation signal for each transmission antenna of the plurality of transmission antennas;
carrying out, by the control device, a check as to whether an individual exposure value established based on the actuation signals lies below a maximum admissible individual exposure limit;
actuating the transmission antennas according to the actuation signals when the individual exposure value established based on the actuation signals lies below the maximum admissible individual exposure limit; and
carrying out a further measure when the individual exposure value established based on the actuation signals does not lie below the maximum admissible individual exposure limit; and
receiving, by the control device, a mode signal from the operator, and making a decision based on the mode signal as to whether the magnetic resonance apparatus is operated in the group mode or in the individual mode.

6. The method of operation of claim 2, wherein the magnetic resonance apparatus is operable in an individual mode, in which the plurality of transmission antennas are actuatable individually,
wherein in the individual mode, the method further comprises:
receiving, from the operator and for the control device, a respective actuation signal for each transmission antenna of the plurality of transmission antennas;
carrying out, by the control device, a check as to whether an individual exposure value established based on the actuation signals lies below a maximum admissible individual exposure limit;
actuating the transmission antennas according to the actuation signals when the individual exposure value established based on the actuation signals lies below the maximum admissible individual exposure limit; and
carrying out a further measure when the individual exposure value established based on the actuation signals does not lie below the maximum admissible individual exposure limit; and
receiving, by the control device, a mode signal from the operator, and making a decision based on the mode signal as to whether the magnetic resonance apparatus is operated in the group mode or in the individual mode.

7. The method of operation of claim 3, wherein the magnetic resonance apparatus is operable in an individual mode, in which the plurality of transmission antennas are actuatable individually,
wherein in the individual mode, the method further comprises:
receiving, from the operator and for the control device, a respective actuation signal for each transmission antenna of the plurality of transmission antennas;
carrying out, by the control device, a check as to whether an individual exposure value established based on the actuation signals lies below a maximum admissible individual exposure limit;
actuating the transmission antennas according to the actuation signals when the individual exposure value established based on the actuation signals lies below the maximum admissible individual exposure limit; and
carrying out a further measure when the individual exposure value established based on the actuation signals does not lie below the maximum admissible individual exposure limit; and
receiving, by the control device, a mode signal from the operator, and making a decision based on the mode signal as to whether the magnetic resonance apparatus is operated in the group mode or in the individual mode.

8. The method of operation of claim 5, wherein carrying out the further measure comprises:
scaling, by the control device, the actuation signals such that a scaled individual exposure value established based on the scaled actuation signals lies below the maximum admissible individual exposure limit; and
actuating the transmission antennas according to the scaled actuation signals.

9. The method of operation of claim 5, wherein the carrying out of the further measure comprises outputting, by the control device, a message to the operator.

10. The method of operation of claim 8, wherein the carrying out of the further measure comprises outputting, by the control device, a message to the operator.
